(19) United States
(12) Patent Application Publication
(10) Pub. No.: US 2014/0069499 A1
(43) Pub. Date: Mar. 13, 2014

(54) MORPHOLOGICAL AND SPATIAL CONTROL OF InP CRYSTAL GROWTH USING CLOSED-SPACED SUBLIMATION

(71) Applicants: Daisuke Kiriya, Berkeley, CA (US); Maxwell Zheng, Berkeley, CA (US); Ali Javey, Lafayette, CA (US)

(72) Inventors: Daisuke Kiriya, Berkeley, CA (US); Maxwell Zheng, Berkeley, CA (US); Ali Javey, Lafayette, CA (US)

(73) Assignee: The Regents of the University of California, Oakland, CA (US)

(21) Appl. No.: 14/014,000

(22) Filed: Aug. 29, 2013

Related U.S. Application Data
(60) Provisional application No. 61/695,889, filed on Aug. 31, 2012.

(51) Int. Cl. H01L 31/0368; H01L 31/0304; H01L 31/18

(52) U.S. Cl. CPC H01L 31/0368; H01L 31/1852; H01L 31/0304
USPC 136/258; 438/93

(57) ABSTRACT

A new solar cell comprising a substrate, a VIB metal thin film deposited on the substrate, and a polycrystalline III-V semiconductor thin film deposited on the VIB metal thin film.

A method of making a solar cell comprising providing a substrate, depositing a VIB metal thin film on the substrate, and depositing a polycrystalline III-V semiconductor thin film on the VIB metal thin film.

In one embodiment, a polycrystalline III-V semiconductor thin film comprising Indium Phosphide (InP) is deposited on a VIB metal thin film comprising Molybdenum (Mo) by Metal Organic Chemical Vapor Deposition (MOCVD). In another embodiment, growth of Indium phosphide (InP) crystals directly on metal foils is described using a method comprising a closed-spaced sublimation (CSS). In another embodiment, both InP nanowires and polycrystalline films were obtained by tuning growth conditions. In another embodiment, utilizing a silicon dioxide mask, selective nucleation of InP on metal substrates was obtained.

### CROSS REFERENCE TO RELATED APPLICATIONS

This U.S. application claims priority to U.S. Provisional Application Ser. No. 61/695,889 filed Aug. 31, 2012, which application is incorporated herein by reference as if fully set forth in their entirety.

### STATEMENT OF GOVERNMENTAL SUPPORT

The invention described and claimed herein was made in part utilizing funds supplied by the U.S. Department of Energy under Contract No. DE-ACO2-05CH11231 between the U.S. Department of Energy and the Regents of the University of California for the management and operation of the Lawrence Berkeley National Laboratory. The government has certain rights in this invention.

### BACKGROUND OF THE INVENTION

1. Field of the Invention

This invention relates generally to solar cells, and, more specifically to polycrystalline (poly) III-V semiconductor solar cells and methods for making the same.

2. Brief Description of the Related Art

III-V semiconductor materials have demonstrated the highest performing photo voltaic (PV) devices in terms of power conversion efficiencies.¹ Indium phosphide (InP) is a good candidate for single junction photo voltaics because it has an ideal band gap² and is reported to have low surface recombination velocity (˜10³ cm s⁻¹)^{3,4,5,6} compared to the other III-V materials such as gallium arsenide (˜10⁶ cm s⁻¹)^{7,8}. For practical applications, however, development of a growth process technique with the following attributes are needed: i) low fabrication costs and large-area manufacturing potential,² ii) spatial control (selective growth) and iii) crystalline morphology control for application specific tailoring of material properties. So far research using metal organic chemical vapor deposition (MOCVD)^{9,10,11} and molecular beam epitaxy (MBE)^{12,13} have been well explored for InP crystal growths, both epitaxially and on metal foils. Specifically, our recent work has shown that non-epitaxially grown InP polycrystalline films on metal foils by MOCVD exhibit near identical optical properties (e.g., photoluminescence spectra) as InP single-crystal wafer.¹¹ This result indicates that polycrystalline InP is a promising material system for high performance PV cells. However, MOCVD and MBE are not suitable for low cost, high throughput manufacturing given their low material utilization yields, expensive precursors, and/or slow growth rates. What is needed in the solar industry is the development of low-cost and yet efficient polycrystalline (poly) III-V solar cells.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a schematic illustration of a close-spaced sublimation (CSS) system.

FIG. 2 illustrates polycrystalline InP growth on a Mo foil.

FIG. 3 illustrates the temperature (T_{sub})-pressure (P) dependence of the InP morphologies grown by CSS.

FIG. 4 illustrates the spatial control of InP crystal growth.

FIG. 5 illustrates the optical properties of the InP crystals on the Mo dots.

FIG. 6 illustrates a mechanism for the growth of polycrystalline InP film in the confined space of CSS.

FIG. 7 illustrates growth conditions for InP nanowires with In-rich tips.

FIG. 8 illustrates growth conditions for straight InP nanowire.

FIG. 9 illustrates growth conditions for polycrystalline InP at T_{sub} below 680° C.

FIG. 10 illustrates fabrication conditions for polycrystalline InP at T_{sub}=685° C.

FIG. 11 illustrates growth conditions for polycrystalline InP at T_{sub}=700° C.

FIG. 12 illustrates (a) SEM image of Mo holes on the foil. (b) InP crystallization on the Mo holes (T_{sub}=685° C., Tₛₒ=800° C., P=1 torr and 30 min growth time). (c) Low magnification SEM image of (b).

FIG. 13 illustrates (a) SEM image of Mo dots on the silicon oxide/silicon wafer. (b) InP crystallization on the Mo dots (T_{sub}=725° C., Tₛₒ=800° C., P=1 torr and 30 min growth time). (c) Low magnification SEM image of (b). (d) A cross-sectional image of the InP crystals on the Mo dots.

FIG. 14 illustrates (a) Mott-Schottky Plot following two minutes of HCl etching, measured in 3M KCl shown in the range of 23718 to 74984 Hz. The simple equivalent circuit is given as an insert. (b) Corresponding frequency dependence of measured carrier concentration.

### DETAILED DESCRIPTION

In the discussions that follow, various process steps are described using certain types of manufacturing equipment, along with certain process parameters. It is to be appreciated that other types of equipment can be used, with different pressure and gas concentrations employed, and that some of the steps may be performed in the same chamber without departing from the scope of this invention. Furthermore, different component gases could be substituted for those described herein without departing from the scope of the invention. These and other details and advantages of the present invention will become more fully apparent from the following description taken in conjunction with the accompanying drawings.

One embodiment of the invention describes a scalable growth method for producing InP crystals directly on metal foils that allows both spatial control (e.g., polycrystalline thin film and selective area growth of crystalline arrays) and morphology control (e.g., from nanowires to faceted crystals) using a close-spaced sublimation (CSS) technique.

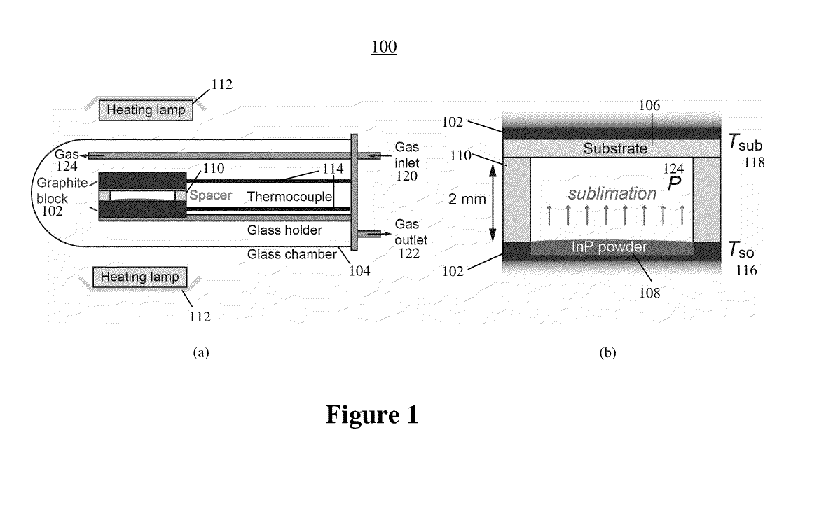

FIG. 1 is a schematic illustration of a CSS system 100. FIG. 1(a) illustrates an overview of the CSS instrument. A glass chamber 104 contains two graphite blocks 102. The substrate 106 and InP precursor powder 108 are located inside the graphite top and bottom blocks 102, respectively. Graphite blocks 102 are heated using halogen lamps 112 while the temperature of the blocks 102 is monitored using thermocouples 114. Atmosphere of the chamber is exchanged using gas inlet 120 and outlet 122 wherein N₂ gas 124 is used. The pressure inside the chamber is also controlled by adjusting the N₂ gas flow. FIG. 1(b) illustrates an enlarged image of the sublimation component of the chamber. Controlled parameters are substrate temperature (T_{sub}) 118, source InP powder temperature (Tₛₒ) 116, pressure of the system (P) 124 and growth time.

The CSS technique¹⁴ provides a small precursor transport distance, which allows efficient transfer of source material to the substrate. Therefore, CSS provides a high crystalline growth rate and potentially high throughput with minimal source material loss.¹⁵ CSS is an established method for making polycrystalline thin-film solar cells, especially for CdTe with the explored device efficiencies of 17.3%¹⁶ which highlights its ability to yield high quality crystal growth. In various embodiments, we describe that the enclosed space facilitates saturated vapor phases of the source materials, thereby enabling nucleation and growth of high quality InP crystals with promising optical properties as examined by steady-state and time-resolved photoluminescence analyses. CSS grown InP is thus a promising candidate for use in thin film III-V solar cells.

### Results and Discussions

FIG. 1 illustrates an overview of the CSS system 100. It includes two graphite blocks 102 encapsulated in a glass chamber 104. The top and bottom graphite blocks 102 partially enclose a substrate 106 and the InP source powder 108, respectively, and these are separated by a spacer 110 (thickness˜2 mm). The temperature of each graphite block 102 is controlled by separate halogen lamps 112 and monitored by separate thermocouples 114. The important parameters in a CSS system are i) the temperatures of the source material (Tₛₒ) 116 and the growth substrate (T_{sub}) 118, ii) chamber pressure (P) 124, iii) and growth time. Thus, these four parameters were explored for growth condition optimization. Additionally proper choice of substrate 106 is critical. In one embodiment, molybdenum (Mo) foil is chosen due to: i) a lack of any In—Mo intermetallics up to the growth temperature, and ii) very low solubility of In at the growth temperature.¹¹ Additionally, the thermal coefficient of Mo is similar to InP.¹⁷

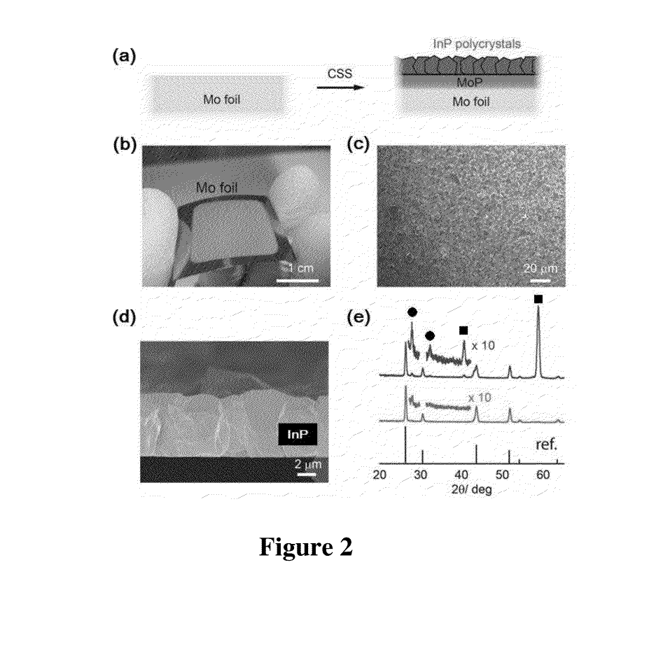

FIG. 2 illustrates polycrystalline InP growth on a Mo foil. FIG. 2(a) illustrative image before (left) and after (right) the growth of a polycrystalline InP film on a Mo foil. FIG. 2(b) macroscopic picture of uniform InP polycrystalline film fabricated on a Mo foil. FIG. 2(c) SEM image of the InP polycrystalline film growth with the condition of (T_{sub}=600° C. (15 min), 680° C. (30 min) then 600° C. (15 min), Tₛₒ=800° C., P=0.2 Torr). The crystalline size is 5-7 μm. FIG. 2(d) Cross-sectional SEM image of a free-standing InP polycrystalline film which delaminated after cutting the foil. The film thickness is estimated to be ˜7 μm. FIG. 2(e) XRD patterns for InP crystals. Curves are normalized to the (111) peak of InP (2θ=26.3°) and offset; (top) Dispersed InP crystals fabricated on Mo foil (T_{sub}=700° C., Tₛₒ=750° C., P=1 Torr; 30 min growth), (110) and (200) of Mo peaks (▪) and (001) and (100) of MoP peaks () were labeled; (middle) InP polycrystalline continuous film on a Mo foil (T_{sub}=685° C., Tₛₒ=800° C., P=1 Torr, 30 min growth); (bottom) reference peaks of InP from International Centre for Diffraction Data (ICDD) Powder Diffraction File (PDF), from left to right, the InP peaks are as follows: (111), (200), (220), (311), (222), and (400).

By sublimation of InP powder, polycrystalline InP was grown on Mo foil as illustrated in FIG. 2a. From visual inspection, the grown InP films exhibited large area (2 cm×2 cm) uniformity (FIG. 2b). FIGS. 2c, d show the top- and side-view scanning electron microscope (SEM) images of a representative polycrystalline InP thin film (˜7 μm thickness) grown on Mo foil. The average grain size for this growth condition is ˜5 μm. The crystalline size and morphology are highly dependent on the growth condition (vide infra) and the most continuous polycrystalline film was obtained using T_{sub}=600° C. (15 min), 680° C. (30 min), then 600° C. (15 min) and Tₛₒ=800° C. and P=0.2 Torr in the growth procedure (FIG. 2c, d). The first and last T_{sub}=600° C. processes should act to increase the nucleation and the growth rate of the InP crystals. X-ray diffraction (XRD) characterization shows the InP crystalline peaks (FIG. 2e) match those of zincblende InP.^{11,18} No preferential orientation was observed. At lower flux growth conditions (e.g., T_{sub}=700° C., Tₛₒ=750° C., P=1 Torr, and 30 min growth), Mo and MoP peaks^{19,20} are also observed because InP crystals are sparse at this condition; this result is comparable to the previous InP growth using MOCVD.¹¹ Note that from our previous study of InP MOCVD growth on Mo, a self-limiting thin layer (˜50 nm thickness) of MoP is found to form at the Mo/InP interface during the growth.^{Error! Bookmark not defined.} In the case here, we also conclude that the Mo surface is phosphorized during the CSS growth as illustrated in FIG. 2a. We note here that the use of flexible metal foil substrates is compatible with large-scale industrial processes such as roll-to-roll fabrication.²¹

Mott-Schottky measurements were performed to characterize the impurity concentration of the CSS grown InP films. The results indicate that the grown InP is n-type, with an electron carrier concentration in the range of ˜0.8-4.6×10¹⁸ cm⁻³ (see below for measurement details). This relatively high electron concentration could be due to carbon incorporation from the graphite blocks used in the set-up or phosphorous vacancies near the surface, both of which are known to be donors in InP. These unintentional doping sources can be mitigated in the future by coating the graphite blocks by an inert material and/or by mixing in additional phosphorous to the source.

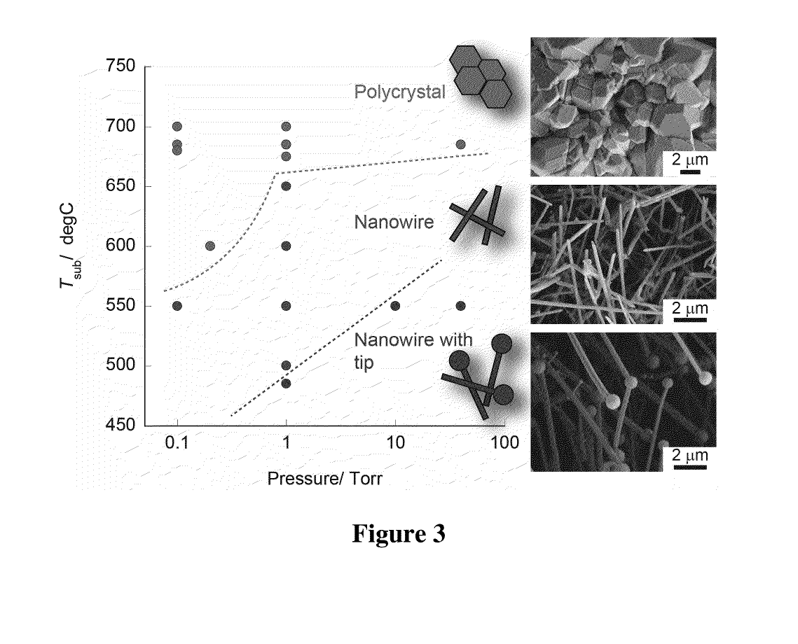

FIG. 3 illustrates temperature (T_{sub})-pressure (P) dependence of the InP morphologies grown by CSS. The SEM images from top to bottom are as followed: polycrystalline film (T_{sub}=685° C., Tₛₒ=800° C., P=1 Torr, 30 min growth), nanowires (T_{sub}=550° C., Tₛₒ=700° C., P=0.1 Torr, 30 min growth), and nanowires with In-rich tips (T_{sub}=550° C., Tₛₒ=700° C., P=10 Torr, 30 min growth). Scale bars are 2 μm.

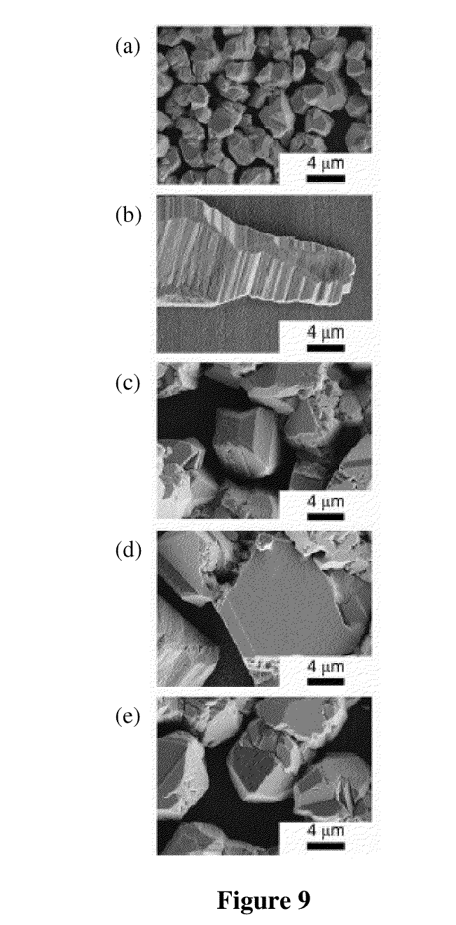

We further examined the temperature and pressure dependency of InP structures. T_{sub} and P determine the growth kinetics of the InP crystals on the substrate, and as shown in FIG. 3, the resulting morphology is highly dependent on these parameters. In the range of T_{sub} between 485° C. to 650° C. with P greater than 1 Torr, we obtained InP nanowires (NWs). The NW morphologies can be categorized into two types: i) NWs with In-rich tips and ii) NWs without tips. The vapor-liquid-solid (VLS) growth mechanism²² is well established for NW growth, and it appears the NWs with tips grow via a VLS mechanism, where an indium droplet first forms on the substrate, followed by absorption of phosphorous from the environment and finally precipitation of InP. On the other hand, the NWs without tips are observed at higher temperatures (above 500° C.). This morphology suggests that both VLS and vapor-solid-solid (VSS) mechanisms are at work. Initially, InP NWs are formed by VLS, and subsequently a VSS process coats the sides. This agrees well with previous reports of NWs fabricated in metal organic vapor phase epitaxy.²² At higher temperature (T_{sub}>650° C. and P>1 Torr), we obtained faceted (polycrystalline) InP crystals as shown in FIGS. 2c, d and FIGS. 9-11. Though not exhaustive, our study clearly shows CSS can controllably produce morphologies ranging from NWs to polycrystalline films by varying the growth conditions. Therefore, application-specific structures can be engineered. For example, water-splitting and catalysis may benefit from the NW structures because of the large surface area, while faceted crystals may be better for fabricating high efficiency solar cells.

Next we examined the time dependence of the CSS InP growth mechanism. 30 min and 60 min growths were performed with all other conditions fixed (T_{sub}=685° C., Tₛₒ=800° C., P=0.1 Torr and 0.5 g InP source).

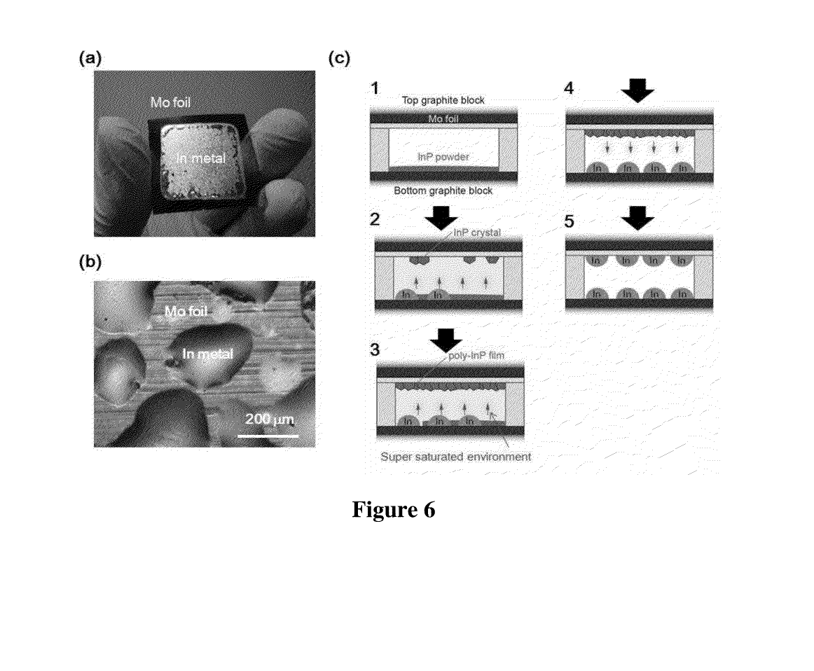

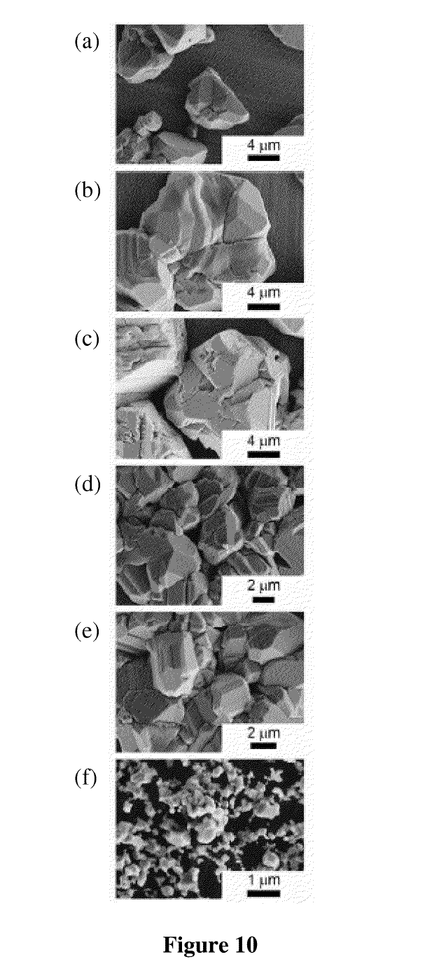

FIG. 6 illustrates a mechanism for the growth of polycrystalline InP film in the confined space of CSS. Figs (a, b) The growth time of 60 min produces indium metal bumps on Mo foil, not InP. The condition is as follows: Tₜₒₚ=685° C., T_{btm}=800° C., P=0.1 Torr, and 60 min annealing time. This condition is the same as the 30 min growth shown in FIG. 10 except for the doubled growth time. The time it takes for phosphorous to run out depends on the amount of InP source. Fig. (c) The mechanism of the InP polycrystalline film fabrication process in CSS system. 1: initial state. 2: initial sublimation. Phosphorous sublimates more rapidly and some indium was left on the bottom graphite. 3: InP film is kept constant because the close space became saturated by phosphorous (and indium) gas. The gas pushes the equilibrium to the crystallization of InP. 4: Further growth time of the CSS system. After running out of phosphorous in the InP powder source on the bottom graphite, decomposition of the top polycrystalline InP film starts. 5: Eventually, phosphorous in both the top and bottom runs out. Only indium residue remained on both the top and bottom graphite blocks.

FIG. 6 shows the results for 60 min sublimation time; silver-colored bumps were obtained on the Mo foil which were In metal (157° C. melting point), not InP. FIG. 10 illustrates fabrication conditions for polycrystalline InP at T_{sub}=685° C. The data indicates that temperature of source (Tₛₒ) does not affect the crystalline morphology. On the other hand, the 30 min growth at the same conditions produced the InP crystalline phase (FIG. 2e and FIG. 10). According to these results, we describe the CSS growth mechanism shown in FIG. 6. During the initial sublimation processes (FIG. 6c step 1 to 2), both indium and phosphorous sublimate resulting in a net flux towards the substrate and InP crystals growth. After some time (step 3), further annealing leads to net phosphorous flux away from both the source and substrate, causing the InP crystals on the substrate to decompose (step 4). Eventually, indium bumps on Mo foil are obtained (step 5). Here we note that we kept T_{sub} the same in all steps 1 to 5, revealing that T_{sub}=685° C. is high enough to decompose InP. Therefore, the InP crystals are grown at higher temperature than their decomposition temperature; this indicates that both phosphorous and indium gases are “super-saturated” through the growth process. This super-saturation pushes the equilibrium shown in eqn. (1)²³ towards formation of InP crystals.

InP(solid) [symbol] In(liquid/gas)+¼P₄(gas) (1)

The super-saturated environment, facilitated by the confined space in a CSS system, also enables us to operate above the disassociation temperature. Therefore, crystals are synthesized at a higher temperature, which potentially allows the growth of higher quality crystals.

Spatial control of the crystalline growth is important for a variety of applications. Primarily, for solar cells the benefits include reducing grain boundaries²⁴ which act as recombination centers and shunt paths^{24,25}. In this context, we examined the selective growth of InP crystals using the CSS technique.

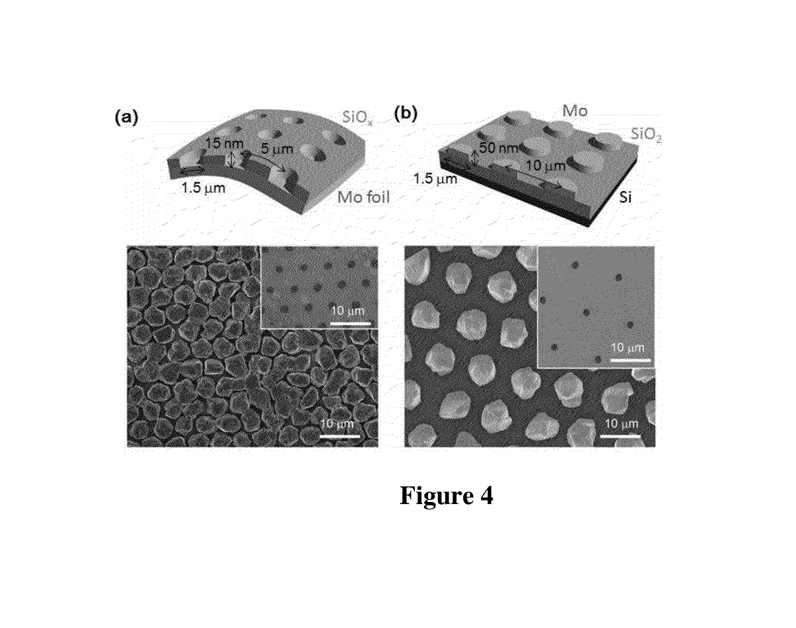

FIG. 4 illustrates spatial control of InP crystal growth. (a) (Top) Illustrative image of Mo holes on the foil covered with silicon oxide. (Bottom) SEM images of the InP crystal growth on the Mo holes and (Inset) the patterned foil before the CSS growth. (b) (Top) Illustrative image of Mo dots on a silicon substrate covered with silicon oxide. (Bottom) SEM images of the InP crystal growth on the Mo dots and (Inset) the patterned substrate before the CSS growth. Scale bars are 10 μm.

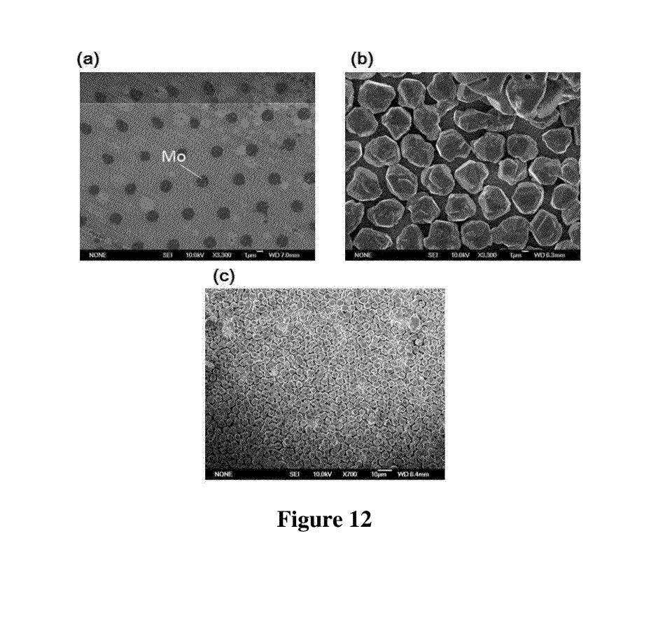

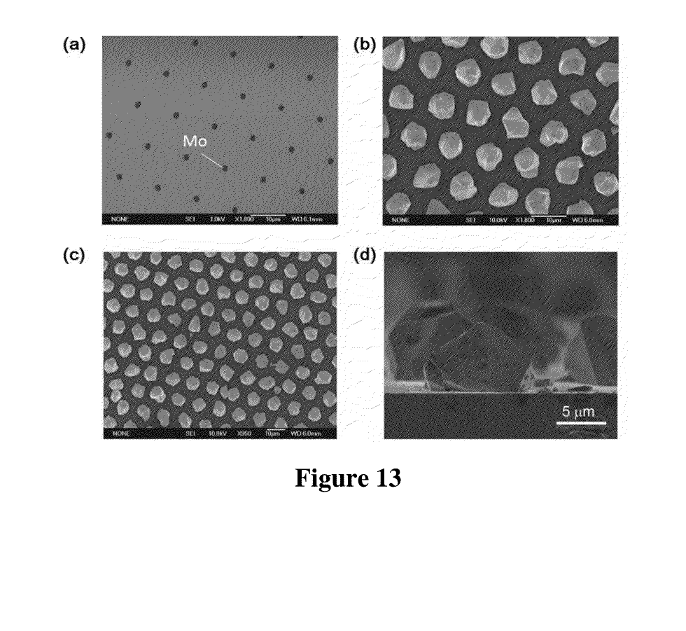

Two types of substrates were examined, Mo holes/dots on silicon oxides as shown in FIG. 4. Mo holes (1.5 μm diameter) are made by depositing 15 nm silicon oxide layer an electron beam evaporator on a Mo foil, followed by patterned etching of the SiOₓ layer. InP growth only occurred on the Mo holes; each crystal (about 5 μm diameter) sat on the Mo holes without any InP nucleation on the SiOₓ surface (FIG. 4a and FIG. 12). The reason is that InP growth is strongly inhibited on silicon oxide surfaces.¹³ In the second type of substrate, 50 nm thick sputtered Mo dots (1.5 μm diameter) were patterned on a silicon oxide/silicon wafer (thermal oxide, 50 nm thickness) using traditional photolithography and lift-off processes. 5 to 7 μm InP crystals were then selectively grown on the Mo dots. The InP crystals are separate from each other and nearly all look like single crystals, which can be seen from a cross-sectional SEM view. Each crystal was about 7 μm in height (FIG. 13). As demonstrated here, controlled growth of InP crystals on both Mo holes and dots is possible, which can facilitate the use of CSS for making precise optoelectronic devices.

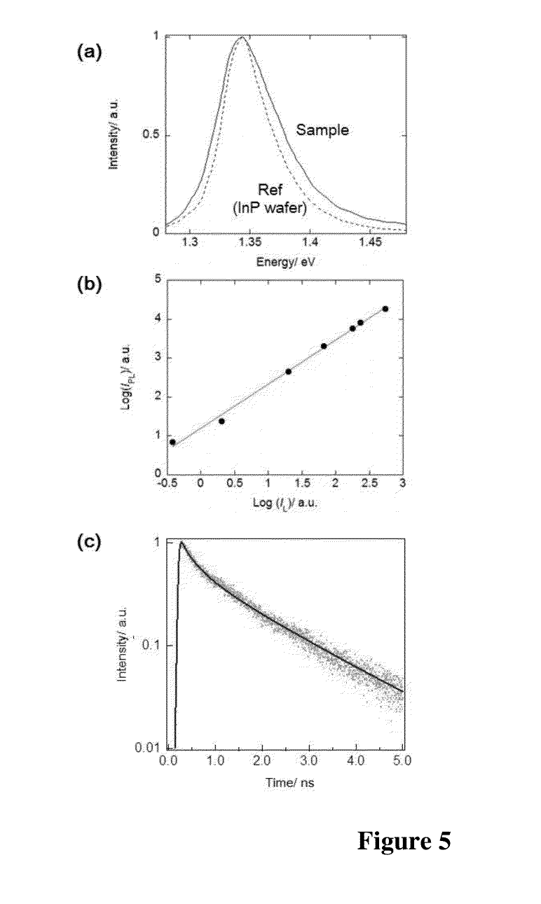

FIG. 5 illustrates optical properties of the InP crystals on the Mo dots. (a) PL spectra of CSS grown InP sample (solid line) and an InP reference wafer (dashed line, electron concentration is 8×10¹⁵ cm⁻³). (b) Laser power (I_{L}) vs PL intensity (I_{PL}) plot. The red line is a linear fit with a slope of ˜1.13. (c) TRPL plot and the simulated curve (solid line) of the InP crystals on Mo dots. The sample was treated by 2 min 1% HCl and 2 min 15% HNO₃ in advance.

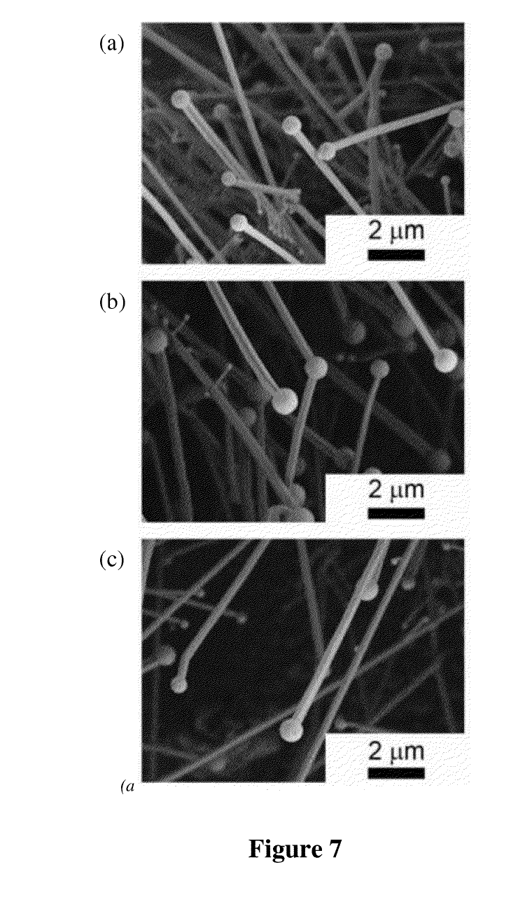

FIG. 7 illustrates growth conditions for InP nanowires with In-rich tips. Table 1 below specifies the growth conditions.

TABLE 1

| | Tsub (° C.) | Tso (° C.) | P (Torr) | Growth time (min) |
|---|---|---|---|---|
| FIG. 7(a) | 485 | 650 | 1 | 30 |
| FIG. 7(b) | 550 | 700 | 10 | 30 |
| FIG. 7(c) | 550 | 700 | 40 | 30 |

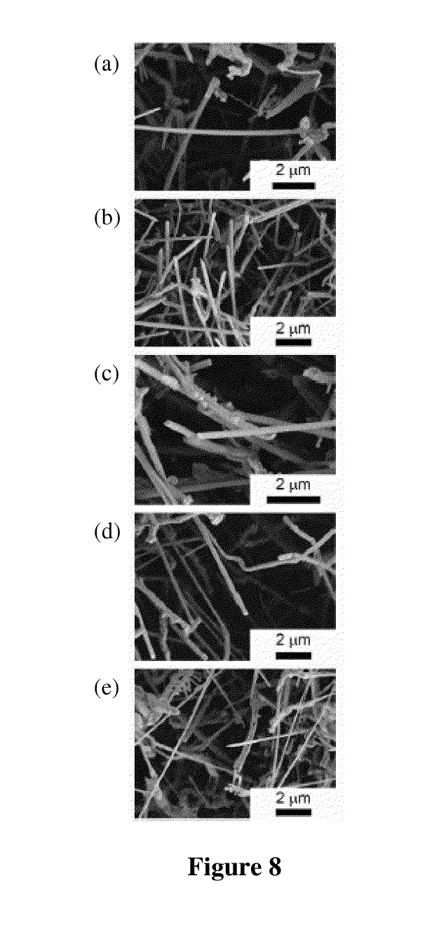

FIG. 8 illustrates growth of straight InP nanowire. Table 2 below specifies the growth conditions.

TABLE 2

| | Tsub (° C.) | Tso (° C.) | P (Torr) | Growth time (min) |
|---|---|---|---|---|
| FIG. 8(a) | 500 | 700 | 1 | 30 |
| FIG. 8(b) | 550 | 700 | 0.1 | 30 |
| FIG. 8(c) | 550 | 700 | 1 | 30 |
| FIG. 8(d) | 600 | 700 | 1 | 30 |
| FIG. 8(e) | 650 | 700 | 1 | 30 |

FIG. 9 illustrates growth of polycrystalline InP at T_{sub} below 680° C. Table 3 below specifies the growth conditions.

TABLE 3

| | Tsub (° C.) | Tso (° C.) | P (Torr) | Growth time (min) |
|---|---|---|---|---|
| FIG. 9(a) | 600 | 800 | 0.2 | 15 |
| FIG. 9(b) | 675 | 750 | 1 | 30 |
| FIG. 9(c) | 675 | 785 | 1 | 60 |
| FIG. 9(d) | 675 | 800 | 1 | 60 |
| FIG. 9(e) | 680 | 800 | 0.1 | 30 |

FIG. 10 illustrates growth of polycrystalline InP at T_{sub}=685° C. Table 4 below specifies the growth conditions.

TABLE 4

| | Tsub (° C.) | Tso (° C.) | P (Torr) | Growth time (min) |
|---|---|---|---|---|
| FIG. 10(a) | 685 | 700 | 1 | 30 |
| FIG. 10(b) | 685 | 785 | 0.1 | 30 |
| FIG. 10(c) | 685 | 785 | 1 | 30 |
| FIG. 10(d) | 685 | 800 | 1 | 30 |
| FIG. 10(e) | 685 | 800 | 1 | 30 |
| FIG. 10(f) | 685 | 800 | 40 | 30 |

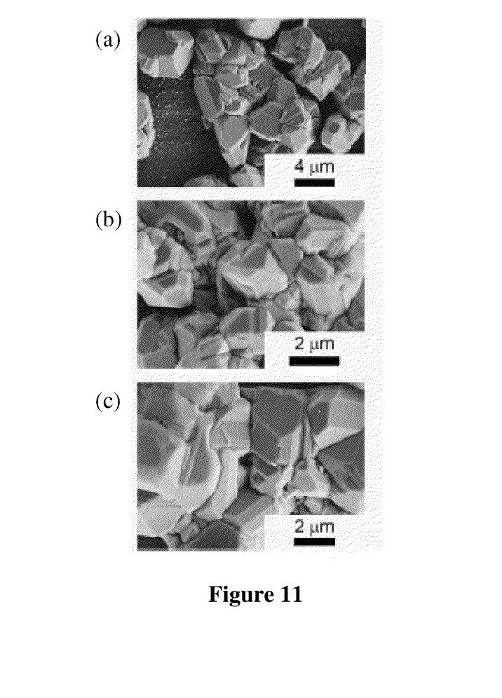

FIG. 11 illustrates growth of polycrystalline InP at T_{sub}=700° C. Table 5 below specifies the growth conditions.

TABLE 5

| | Tsub (° C.) | Tso (° C.) | P (Torr) | Growth time (min) |
|---|---|---|---|---|
| FIG. 11(a) | 700 | 750 | 0.1 | 30 |
| FIG. 11(b) | 700 | 750 | 1 | 30 |
| FIG. 11(c) | 700 | 750 | 1 | 30 |

FIG. 13 illustrates (a) SEM image of Mo dots on the silicon oxide/silicon wafer. (b) InP crystallization on the Mo dots (T_{sub}=725° C., Tₛₒ=800° C., P=1 torr and 30 min growth time). (c) Low magnification SEM image of (b). (d) A cross-sectional image of the InP crystals on the Mo dots. The height of the crystal is about 7 μm. The cross-sectional image indicates the crystal is composed of a single domain.

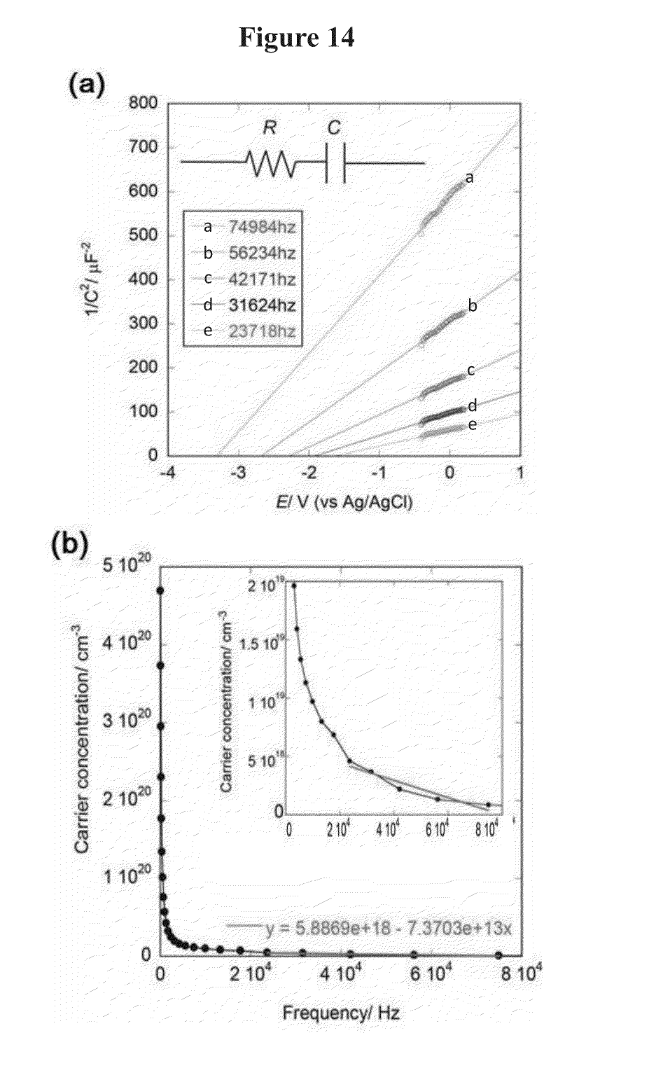

FIG. 14 illustrates (a) Mott-Schottky Plot following 2 minutes of HCl etching, measured in 3M KCl shown in the range of 23718 to 74984 Hz. The simple equivalent circuit is given as an insert. (b) Corresponding frequency dependence of measured carrier concentration. The free electron concentration was indicated as 0.8-4.6×10¹⁸ cm⁻³. The high doping concentration could be from carbon from the graphite blocks or phosphorous vacancies, both of which are known to be donors. The first possibility can be solved by coating the graphite blocks and the second can be solved by mixing in additional phosphorous to the source.

Mott-Schottky measurements were performed to characterize the impurity concentration of the CSS grown InP films. According to a previous report, the charge carrier concentration can be estimated from the slope of the 1/C² vs. electrode potential plot, where C indicates capacitance. The results of the Mott-Schottky analyses in the range of 99 to 8×10⁴ Hz are shown in FIG. 14b. The determination of the carrier concentration is most reliable for frequencies between 2×10⁴ and 8×10⁴ Hz, where the depletion capacitance dominates. The results indicate that the grown InP is n-type, with an electron carrier concentration in the range of ˜0.8-4.6×10¹⁸ cm⁻³.

We further analyzed the optoelectronic properties of InP crystals. Room temperature steady-state photoluminescence (PL) spectra (FIG. 5a) of InP crystals on Mo dots show an asymmetric feature with the peak at ˜1.34 eV. Compared to an 8×10¹⁵ cm⁻³ n-InP single-crystal wafer, the peak position is nearly the same and the full-width-at-half-maximum (FWHM) is slightly broader (0.060 eV vs. 0.045 eV). This result shows the high optical quality of our CSS grown InP. The slight peak broadening can be explained by a higher carrier concentration in our material,²⁶ which is corroborated by the doping levels (0.8-4.6×10¹⁸ cm⁻³) extracted from Mott-Schottky measurements on thin films (FIG. 14). To further analyze the quality of the crystals from the underlying recombination processes, a study of the photoluminescence intensity as a function of incident laser power was performed (FIG. 5b). The result suggests that exciton recombination dominates. This relationship can be seen in a log-log plot (FIG. 5b), for which the relation is given by I_{PL}=CI_{L}^{k}, where I_{PL} is the PL intensity, I_{L} is the illumination power, C is a proportionality constant, and k is the power dependence of the PL intensity.²⁷ For a direct band gap material, a value of k<1 is expected for free-to-bound recombination (electron to acceptor or hole to donor), k=1 is expected for free or bound exciton recombination, and k=2 is expected when defect state recombination dominates²⁷. We find k=1.13±0.03 by a linear fit to the log-log plot. This result provides additional evidence for a high optical quality film, as the close value of k˜1 indicates defect (nonradiative) recombination is not significant.

To determine the carrier lifetime, time-resolved photoluminescence (TRPL) measurements were carried out for the InP crystals on Mo dots (FIG. 5c). The sample was illuminated with 800 nm incident light at illumination power of P₀=440 mW and a spot size of A=π*200² μm², giving an excess carrier concentration of ˜6×10¹⁷ cm⁻³ at the surface; the generation rate is given by G=α*P₀/(Eₚₕ*A), where absorption coefficient (α)=3.37×10⁴ cm⁻¹, and the photon energy (Eₚₕ)=1.55 eV. The TRPL decay time (1/e) of our sample is 0.89 ns. The previously reported TRPL decay time in an InP single-crystalline film grown by the liquid phase epitaxial process is 0.94 ns for the doping concentration of 5.3×10¹⁸ cm⁻³.²⁸ This provides further evidence that our CSS grown polycrystals have similar quality as InP single crystals. Further, the diffusion equation was solved to simulate a TRPL decay curve. The fitting parameters were bulk recombination lifetime (τ) and effective surface recombination velocity (SRV) at the top surface. Due to the thickness of the sample (˜7 μm), the lifetime was insensitive to back surface recombination, which was therefore not considered here. The simulated decay curve was then convolved with the measured instrument response and fit to the experimentally measured curve (FIG. 5c). Using an ambipolar diffusion coefficient of 5.2 cm²/s, and a bulk electron concentration of 3×10¹⁸ cm⁻³, τ and effective SRV were extracted to be 3.0 ns and 1.9×10⁵ cm s⁻¹, respectively. This SRV value is higher than previous TRPL results for n-type InP^{3,4,5,6,7}; however, it should be possible to reduce this by appropriate surface treatment. It should be noted that the ambipolar diffusion coefficient was calculated using electron and hole mobilities of single crystalline InP for the same carrier concentration. In the future, detailed Hall effect measurements need to be performed to more directly assess the diffusion coefficients and thereby the carrier lifetimes. TRPL studies on single crystal n-InP with similar concentrations have not extracted the bulk recombination time in the past.

### CONCLUSIONS

Various embodiments demonstrate morphology and spatial control of InP grown on Mo foil using the CSS technique. The crystals grown using this technique are composed of micron-sized grains, and show good carrier lifetimes as measured by TRPL characteristics. The confined space allows supersaturation of the source gases enabling growth at higher temperatures, which promotes high quality InP crystals. In the future, further characterization of the minority carrier lifetime, mobility, and diffusion length are needed. Appropriate dopants, substrates and surface modifications will also be explored for making high quality opto-electronic devices. Our growth scheme sublimates a powder inside the chamber and avoids using expensive systems and single-crystalline substrates, which is a limiting factor in current III-V growth technologies. The use of metal foil substrates is important to not only reduce cost at the material growth step, but also at downstream processing steps given its mechanical properties. Therefore, InP grown using CSS shows promise for high-efficiency and low-cost solar cells.

### Experimental Section

Chemicals.

The following commercially available materials were obtained, indium phosphide (InP) powder (China Rare Metal Material Co.), PMMA 495 C2 (Microchem Co.), and remover-PG (Microchem Co.).

CSS System and Growth Procedures.

The CSS system used here was built by Engineered Science. The glass chamber size was about 10-inch long and 5-inch diameter. The glass folder held graphite blocks. Inside the graphite blocks precursor InP powder (99.999%, China Rare Metal Co.) and Mo foil (99.95%) were sandwiched. The spacer thickness was ˜2 mm. The chamber was evacuated and purged with N₂ gas. Growth substrate and source temperatures ranged from T_{sub}=485 to 700° C. and Tₛₒ=650 to 800° C., respectively. Growth times explored were 30-60 minutes and pressure range was 0.1 to 40 TOM. The Mo foils used were 25 μm thick and cleaned with acetone and isopropanol prior to growth.

Fabrication of Patterned Mo Substrates.

Mo dots on silicon oxide were fabricated as follows: 50 nm thick, 1.5 μm diameter Mo circles on silicon oxide/silicon wafer were fabricated using a standard lift-off process. The thickness of silicon oxide was 50 nm, and the Mo was deposited via sputtering. The Mo holes were fabricated as follows: 15 nm silicon oxide (SiOₓ) was deposited on Mo foil by electron-beam evaporation. A photo resist (PMMA 495 C2) was spincoated (3000 rpm, 1 min) on the Mo foil (25 μm). The foil was baked for 1 min at 180° C. on a hotplate. Acetone was then poured onto a patterned polydimethylsiloxane (PDMS, same dot pattern as shown in FIG. 3a), and the PDMS put onto the foil for 1 h. The PDMS dot pattern was subsequently transferred to the foil. Finally, the SiOₓ was etched using 0.2% HF, and the photoresist removed by remover-PG.

Physical Measurements.

The XRD was taken on a Bruker AXS D8 Discover GADDS XRD Diffractometer system. The PL excitation source was a 785 nm laser with ˜5 μm spot size, and the detector was a silicon CCD. The TRPL excitation source was a tunable Mira 900-F Ti-sapphire laser set to 800 nm, producing 200 fs pulses at 75.3 MHz. The detector was a Si APD (id-100) produced by id Quantique hooked up to a TCSPC module (SPC-130) from Becker & Hickl. The sample (InP crystals on Mo dots shown in FIG. 4b) for PL and TRPL measurements was treated by 2 min 1% HCl and 2 min 15% HNO₃ in advance. These treatments removed surface oxides and passivated the InP crystals.^{29,30} SEM images were taken on a Zeiss Gemini Ultra-55 and JEOL 6340F. The Mott-Schottky measurements were performed with a SP-300 Potentiostat set-up (BioLogic, France) for the InP polycrystalline film (T_{sub}=600° C. (15 min), 680° C. (30 min) then 600° C. (15 min), Tₛₒ=800° C., P=0.2 Torr) in 3.0 M KCl solution. Before the measurement, the InP polycrystalline film was transferred to a glass substrate by peeling it off from the Mo foil using glue. The InP polycrystalline film was covered by a glue (Advanced Formula Instant Krazy Glue, Elmer's Products, Inc), then lifted off from the Mo foil after curing of the glue. The sample was etched before the measurement by 1 M HCl for 2 min to remove any residual MoP that peeled off. Mott-Schottky plots of these data are shown in FIG. S9 for different frequencies. The potential scan started at −0.4 V down to 0.2 V with steps of 20 mV. The frequency range was 99 to 100 kHz. The carrier concentration was calculated from the slope of the 1/C₂ vs potential plot, where C is the capacitance of the space charge layer. According to the frequency dispersion data (FIG. 14b S9b), the free electron concentration was ˜0.8-4.6×10¹⁸ cm⁻³.

### ABBREVIATIONS

CSS, close-spaced sublimation; PV, photo voltaic; InP, indium phosphide; SEM, scanning electron microscope; Mo, molybdenum; MoP, molybdenum phosphide; MOCVD, metal organic chemical vapor deposition; XRD, X-ray diffraction; NW, nanowire; VLS, vapor-liquid-solid; VSS, vapor-solid-solid; PL, photoluminescence; TRPL, time-resolved photoluminescence; SRV, surface recombination velocity.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

### REFERENCES

1. Green, M. A.; Emery, K.; Hishikawa, Y.; Warta, W. Prog. Photovolt: Res. Appl. 2012, 20, 12.
2. Miles, R. W.; Zoppi, G.; Forbes, I. Materialstoday, 2007, 10, 20.
3. Nakamura, T.; Katoda, T.; J. Appl. Phys. 1984, 55, 3064.
4. Rosenwaks, Y.; Shapira, Y.; Huppert, D. Phys. Rev. B, 1991, 44, 13097.
5. Rosenwaks, Y.; Shapira, Y.; Huppert, D. Phys. Rev. B, 1992, 45, 9108.
6. Bothra, S.; Tyagi, S.; Ghandhi, S. K.; Borrego, J. M. Solid-State Electron. 1991, 34, 47.
7. Nolte, D. D. Solid-State Electron. 1996, 33, 295.
8. Jastrzebski, L.; Lagowski, J.; Gatos, H. C. Appl. Phys. Lett. 1975, 27, 537.
9. Saitoh, T.; Matsubara, S.; Minagawa, S. J. Electrochem. Soc. 1976, 123, 403.
10. Saitoh, T. Matsubara, S.; Minagawa, S. J. J. Appl. Phys. 1977, 16, 807.
11. Zheng, M.; Yu, Z.; Seok, T. J.; Chen, Y.-Z.; Kapadia, R.; Takei, K.; Aloni, S.; Ager, J. W.; Wu, M.; Chueh, Y.-L.; Javey, A. J. Appl. Phys. 2012, 111, 123112.
12. Tsang, W. T. Appl. Phys. Lett. 1984, 45, 1234.
13. Araki, K.; Seo, J. U.; Hasegawa, S.; Asahi, H. Phys. Stat. Sol. C, 2008, 9, 2766.
14. Nicoll, F. H. J. Electrochem. Soc. 1963, 110, 1165.
15. Mimila-Arroyo, J.; Diaz, J.; Lusson, A.; Grattepain, C.; Bisaro, R.; Bourgoin, J. C. Mater. Sci. Technol. 1996, 12, 178.
16. First Solar, Jul. 26, 2011 (http://investor.firstsolar.com/releasedetail.cfm?ReleaseID=593994).
17. Bachmann, K. J.; Buehler, E.; Shay and, J. L.; Wagner, S. Appl. Phys. Lett. 1976, 29, 121.
18. ICDD PDF-2, Entry 00-032-0452, 2003.
19. ICDD PDF-2, Entry 00-065-6024, 2003.
20. ICDD PDF-2, Entry 00-089-5156, 2003.
21. Lee, M. H.; Lim, N.; Ruebusch, D. J.; Jamshidi, A.; Kapadia, R.; Lee, R.; Seok, T. J.; Takei, K.; Cho, K. Y.; Fan, Z.; Jang, H.; Wu, M.; Cho, G.; Javey, A. Nano Lett. 2011, 11, 3425.
22. Woo, R. L.; Gao, L.; Goel, N.; Hudait, M. K.; Wang, K. L.; Kodambaka, S.; Hicks, R. F. Nano Lett. 2009, 9, 2207.
23. Weiser, K. J. Phys. Chem. 1957, 61, 513.
24. Zubía, D.; López, C.; Rodríguez, M.; Escobedo, A.; Oyer, S.; Romo, L.; Rogers, S.; Quiñónez, S.; Mcclure, J. J. Elect. Mater. 2007, 36, 1599.
25. Gibson, P. N.; Baker, M. A.; Dunlop, E. D.; Özsan, M. E.; Lincot, D.; Froment, M. Agostinelli, G. Thin Solid Films, 2001, 387, 92.
26. Bugaiski, M.; Lewandowski, W. J. Appl. Phys. 1985, 57, 521.
27. Schmidt, T.; Lischka, K.; Zulehner W. Phys. Rev. B, 1992, 45, 8989.
28. Augustine, G.; Keyes, B. M.; Jokerst, N. M.; Rohatgi, A.; Ahrenkiel R. K. Proc. 5th Int. Conf. Indium Phosphide Related Mater. 1993, 636-639.
29. Krawczyk, S. K.; Hollinger, G. Appl. Phys. Lett. 1984, 45, 870.
30. Bertrand, P. A. J. Vac. Sci. Technol. 1981, 18, 28.

1. A solar cell comprising;
a substrate;
a VIB metal thin film deposited on the substrate; and
a polycrystalline III-V semiconductor thin film deposited on the VIB metal thin film.

2. The solar cell of claim 1 wherein the substrate is a metal.

3. The solar cell of claim 2 wherein the metal substrate is a metal foil.

4. The solar cell of claim 2 wherein the metal substrate is Aluminum (Al).

5. The solar cell of claim 2 wherein the metal substrate is Molybdenum (Mo).

6. The solar cell of claim 2 wherein the metal substrate is Tungsten (W).

7. The solar cell of claim 1 wherein the VIB metal thin film is Molybdenum (Mo).

8. The solar cell of claim 1 wherein the VIB metal thin film is Tungsten (W).

9. The solar cell of claim 1 wherein the polycrystalline III-V semiconductor thin film is Indium Phosphide (InP).

10. The solar cell of claim 1 wherein the polycrystalline III-V semiconductor thin film is Gallium Arsenide (GaAs).

11. The solar cell of claim 1 wherein polycrystalline III-V semiconductor thin film is deposited utilizing Metal Organic Chemical Vapor Deposition (MOCVD).

12. A method of making a solar cell comprising;
providing a substrate;
depositing a VIB metal thin film deposited on the substrate; and
depositing a polycrystalline III-V semiconductor thin film on the VIB metal thin film.

13. The method of claim 12 wherein the substrate is a metal.

14. The method of claim 13 wherein the metal substrate is a metal foil.

15. The method claim 13 wherein the metal substrate is Aluminum (Al).

16. The method of claim 13 wherein the metal substrate is Molybdenum (Mo).

17. The method of claim 13 wherein the metal substrate is Tungsten (W).

18. The method of claim 12 wherein the VIB metal thin film is Molybdenum (Mo).

19. The method of claim 12 wherein the VIB metal thin film is Tungsten (W).

20. The method of claim 12 wherein the polycrystalline III-V semiconductor thin film is Indium Phosphide (InP).

21. The method of claim 12 wherein the polycrystalline III-V semiconductor thin film is Gallium Arsenide (GaAs).

22. The method of claim 12 wherein polycrystalline III-V semiconductor thin film is deposited utilizing Metal Organic Chemical Vapor Deposition (MOCVD).
